(19) United States
(12) Patent Application Publication
(10) Pub. No.: US 2024/0105887 A1
(43) Pub. Date: Mar. 28, 2024

(54) PACKAGE STRUCTURE AND PACKAGING METHOD

(71) Applicant: BRIGHTEK OPTOELECTRONICS CO., LTD. (JIANGSU), Jiangsu (CN)

(72) Inventors: Chih-Hung TZENG, Jiangsu (CN); Chih-Chiang KAO, Jiangsu (CN); Chien-Chung HUANG, Jiangsu (CN)

(21) Appl. No.: 18/264,835

(22) PCT Filed: Apr. 14, 2023
(86) PCT No.: PCT/CN2023/088481

§ 371 Date: Aug. 9, 2023

(30) Foreign Application Priority Data
Mar. 30, 2022 (CN) 202210324399.3
Oct. 9, 2022 (CN) 202211227901.5

(51) Int. Cl. H01L 33/54; H01L 25/075; H01L 33/48; H01L 33/62

(52) U.S. Cl. CPC H01L 33/54; H01L 25/0753; H01L 33/486; H01L 33/62; H01L 2933/005; H01L 2933/0066

(57) ABSTRACT

A package structure, including: a first packaging member having oppositely arranged first surface and second surface; a control chip covered by the first packaging member; a plurality of conductors provided on and protruding from the control chip and electrically connected to electrical contacts of the control chip, the conductors being covered by the first packaging member, and ends of the conductors facing away from the control chip being flush with the first surface; a wire pattern layer disposed on the first surface and electrically connected to the conductors; a light emitting element located on the first surface and electrically connected to the control chip via the wire pattern layer; and a second packaging member covering the light emitting element and affixed to the first surface and the wire pattern layer, a light beam emitted by the light emitting element being allowed to travel outward through the second packaging member.

### CROSS-REFERENCE TO RELATED APPLICATIONS

This disclosure is a 35 U.S.C.§ 371 national stage application of PCT application No. PCT/CN2023/088481, filed on Apr. 14, 2023, which claims the benefit of Chinese Patent Application No. 202210324399.3, entitled PACKAGE STRUCTURE AND PACKAGING METHOD, which was filed with China National Intellectual Property Administration on Mar. 30, 2022, and Chinese Patent Application No. 202211227901.5, entitled PACKAGE STRUCTURE AND PACKAGING METHOD, which was filed with China National Intellectual Property Administration on Oct. 9, 2022, and the entire contents of which are incorporated herein by reference.

### TECHNICAL FIELD

The present disclosure relates to the field of packaging technology, and more particularly, relates to a package structure and a packaging method.

### BACKGROUND

At present, the most commonly used types of package products integrating a Light-Emitting Diode (LED) and a control chip are the same plane wire-bonded package and the upper and lower cups wire-bonded bracket-typed package. These two types of packages are both space consuming due to the reserved space for wire-bonding, and may not have the package size effectively reduced because of the arrangement of the chip and the space for wire-bonding, resulting in an obstacle in practice.

### SUMMARY

In view of this, the present disclosure provides a package structure and a packaging method to solve the technical problem of prior art that the package product integrating an LED and a control chip has large size.

A first aspect of the disclosure provides a package structure, including: a first packaging member having a first surface and a second surface oppositely arranged; a control chip covered by the first packaging member; a plurality of conductors provided on and protruding from the control chip and electrically connected to electrical contacts of the control chip, the conductors being covered by the first packaging member, and ends of the conductors facing away from the control chip being flush with the first surface; a wire pattern layer disposed on the first surface and electrically connected to the plurality of conductors; at least one light emitting element located on the first surface and electrically connected to the control chip via the wire pattern layer; and a second packaging member covering the light emitting element and affixed to the first surface and the wire pattern layer, a light beam emitted by the light emitting element being allowed to travel outward through the second packaging member.

In one embodiment, the second packaging member is made of a light transparent material and the electrical contacts of the control chip are facing the first surface.

In one embodiment, a plurality of electrical connectors are provided inside the first packaging member, the electrical connector is a conducting channel or a conducting cylinder, the electrical connector is perpendicular to the first surface and penetrates the first packaging member, and one end of the electrical connector is connected to the wire pattern layer.

In one embodiment, the control chip is not exposed from the first packaging member, the package structure further includes a plurality of pins, the pin is affixed to the second surface and connected to one end of the electrical connector away from the wire pattern layer, and electrical contacts of the light emitting element are facing the first surface.

In one embodiment, the package structure further includes a metal member, the metal member is provided on one side of the control chip away from the conductors and covers at least part of a surface of the control chip, and the metal member is covered by the first packaging member.

In one embodiment, a side of the metal member facing away from the control chip is flush with the second surface, and the package structure further includes a grounded zone provided on the second surface; and the grounded zone is electrically connected to the metal member, and the grounded zone is electrically connected to one of the conductors through one of the electrical connectors and the wire pattern layer.

In one embodiment, the package structure further includes a third packaging member, and the third packaging member is connected to the first packaging member and surrounds a peripheral side of the second packaging member connecting to the first surface; both the third packaging member and the first packaging member are made of opaque material; a side of the third packaging member facing away from the first surface is flush with a side of the second packaging member facing away from the first surface, and an outer side of the third packaging member perpendicular to the first surface is flush with an outer side of the first packaging member perpendicular to the first surface.

In one embodiment, the package structure includes a plurality of the light emitting elements and the plurality of light emitting elements are located in the middle of the first surface; or, a projection of the plurality of light emitting elements on the first surface overlaps at least partially with a projection of the control chip on the first surface.

In the package structure provided in the disclosure, the control chip is entirely encapsulated by the first packaging member and electrically connected to the wire pattern layer via the conductors. Since the wire pattern layer and the light emitting element(s) are both arranged on the first packaging element and encapsulated with the second packaging member, the light emitting element(s) and the control chip are allowed to be vertical stacked, which effectively organizes the spatial arrangement. As compared with the existing flat package, the package structure provided in this disclosure has reduced size, effectively solving the technical problem that the package product integrating the LED and the control chip has large size.

A second aspect of this disclosure provides a packaging method for preparing the package structure according to any one of the embodiments of the first aspect, includes:
preparing a plurality of conductors on a control chip, the conductors being electrically connected to electrical contacts of the control chip; covering the control chip and the plurality of conductors with a first packaging member, the control chip not being exposed from the first packaging member; preparing a wire pattern layer on a first surface of the first packaging member, the wire pattern layer being electrically connected to the plurality of conductors; mounting at least one light emitting element on one side of the wire pattern layer away from the first packaging member; and covering the light emitting element with a second packaging member, the second packaging member being affixed to the first surface and the wire pattern layer.

In one embodiment, the packaging method further includes: surrounding a peripheral side of the second packaging member connecting to the first surface with a third packaging member; wherein said preparing a plurality of conductors on the control chip includes preparing the conductors by a wafer bumping process or a metal placement process; and prior to said covering the control chip and the plurality of conductors with a first packaging member, the method further includes preparing a metal member, the metal member being provided on one side of the control chip away from the conductors.

The above packaging method allows the light emitting element(s), the wire pattern layer, the conductors and the control chip to be vertically stacked, which may reduce the required planar space, and thus reduce the size of the package structure. In the package structure, the light emitting element(s) may be electrically connected to the control chip via the wire pattern layer and the conductors, which reduces wire patterning. As the opaque first packaging member encapsulates the control chip entirely, no additional substrate is needed, and potential issues such as contamination, mechanical damage resulted from an exposed control chip may be avoided.

### BRIEF DESCRIPTION OF THE DRAWINGS

To more clearly illustrate the technical solutions in the embodiments of the disclosure, the figures to be referenced in the description of the embodiments or prior art will be briefly described in the following. Apparently, the described figures are merely some of the embodiments of the present disclosure, and it is possible for those skilled in the art to obtain other figures on the basis of these figures without paying creative labor.

FIG. 1 is a side view of a package structure provided in a first embodiment of this disclosure;

FIG. 2 is a schematic diagram of the package structure shown in FIG. 1;

FIG. 3 is a top view of the package structure shown in FIG. 1;

FIG. 4 is a schematic diagram of a package structure provided in a second embodiment of this disclosure;

FIG. 5 is a top view the package structure shown in FIG. 4;

FIG. 6 is a bottom view of the package structure shown in FIG. 4;

FIG. 7 is a flow chart of a packaging method provided in a third embodiment of this disclosure;

FIG. 8 is a schematic diagram of a structure of a control chip and a plurality of conductors which is packaged with a first packaging member in the packaging method provided in the third embodiment of this disclosure;

FIG. 9 is a schematic diagram of the structure in which a first surface of the first packaging member is provided with a wire pattern layer in the packaging method provided in the third embodiment of this disclosure;

FIG. 10 is a schematic diagram of the structure in which at least one light emitting element is mounted on the wire pattern layer at its side away from the first packaging member in the packaging method provided in the third embodiment of this disclosure;

FIG. 11 is a schematic diagram of the structure in which the light emitting element is packaged with a second packaging member in the packaging method provided in the third embodiment of this disclosure;

FIG. 12 is a schematic diagram of the structure in which the second packaging member is diced in the packaging method provided in the third embodiment of this disclosure;

FIG. 13 is a schematic diagram of the structure in which the light emitting element is packaged with a second packaging member in the packaging method provided in a fifth embodiment of this disclosure;

FIG. 14 is a schematic diagram of the structure in which the second packaging member is diced in the packaging method provided in the fifth embodiment of this disclosure;

FIG. 15 is a schematic diagram of the structure in which a gap is filled with a third packaging member in the packaging method provided in a fifth embodiment of this disclosure.

The reference numbers in the figures are:
100, package structure;
10, first packaging member; 11, first surface; 12, second surface; 13, electrical
connector;
20, control chip; 201, control zone;
30, conductor;
40, wire pattern layer;
50, light emitting element;
61, second packaging member; 62, third packaging member; 63, grounded
zone; 64, extension electrode sheet;
70, pin;
80, metal member;
91, cut unit; 92, gap.

### DETAILED DESCRIPTION OF THE EMBODIMENTS

In order to make the purposes, the technical solutions and the advantages of this disclosure clearer, this disclosure will be further described in detail below with reference to the accompanying drawings and embodiments. It should be understood that the specific embodiments described herein are merely illustrative of this disclosure and are not intended to limit this disclosure.

It should be understood that in the description of this disclosure, an orientation or positional relationship indicated by the terms “length”, “width”, “up”, “down”, “front”, “back”, “left”, “right”, “vertical”, “horizontal”, “top”, “bottom”, “inside”, “outside” and the like is an orientation or positional relationship shown in the drawings, and is merely for the convenience of describing this disclosure and simplifying the description, rather than indicating or implying that the device or elements referred to have a particular orientation, and are configured and operated along a particular orientation. Thus, it cannot be construed as limiting this disclosure.

In addition, terms “first” and “second” are only adopted for description and should not be understood to indicate or imply relative importance or implicitly indicate the number of indicated technical features. Therefore, a feature defined by “first” and “second” may explicitly or implicitly indicate inclusion of one or more of such features. In the description of this disclosure, “a plurality of” means two or more, unless otherwise limited definitely and specifically.

In this disclosure, unless otherwise definitely specified and limited, the terms “mounted”, “connected”, “connecting”, “fixed” and the like should be understood in a broad sense, for example, they may refer to a fixed connection, or a removable connection, or in one piece; they may refer to a mechanical connection or an electrical connection; they may refer to a direct connection or an indirect connection through an intermediate medium, or an internal communication between two components or an interaction relationship between two components. To those skilled in the art, the specific meaning of the above terms in this disclosure may be understood on a case-by-case basis.

To illustrate the technical solutions described in this disclosure, the following are described with reference to the specific accompanying drawings and embodiments.

Please refer to the first and second embodiments for the details. A first embodiment of the present disclosure provides a package structure applicable for packaging a product integrating an LED and a controller chip, for example, a Mini LED integrated with a control chip in particular which may serve as a light source and be used for transparent displays. The package structure effectively organizes the spatial arrangement, uses a multi-layer molding process and integrated wire patterning to make the prior flat package into a vertical stacking package, and allows for a flip-chip package, which largely reduces the thickness of the product integrating the LED and the control chip.

### First Embodiment

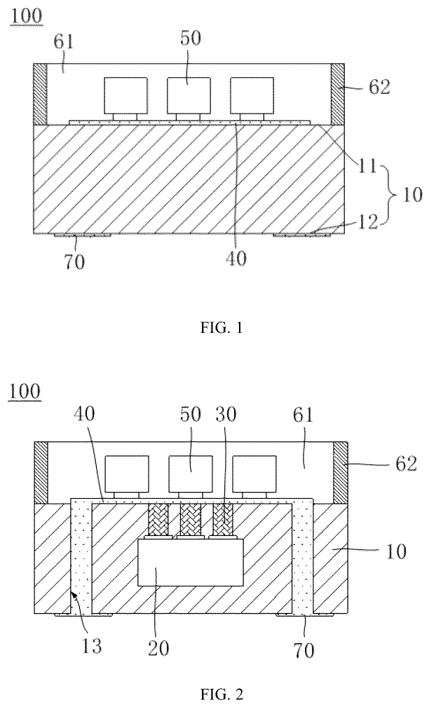

Please refer to FIGS. 1 and 2. The embodiment of the present disclosure provides a package structure 100, which includes a first packaging member 10, a control chip 20, a plurality of conductors 30, a wire pattern layer 40, at least one light emitting element 50 and a second packaging member 61, where the control chip 20 is used for receiving external signals and controlling the light emitting element 50 to emit light.

The first packaging member 10 has oppositely arranged first surface 11 and second surface 12, and the control chip 20 is encapsulated by the first packaging member 10. For example, the control chip 20 is completely encapsulated inside the first packaging member 10, that is, the control chip 20 is not exposed from the first packaging member 10, so that the control chip 20 may be protected from mechanical damage, and an additional bonding process, which secures the control chip 20 on a substrate, may be omitted from the manufacturing process, thereby a potential failure problem that the chip falls off a warped substrate may be avoided. In addition, the omission of the bonding process may save costs and effectively avoid a potential risk of thermal stress formation without using an underfill. The first packaging member 10 may be opaque epoxy resin such as black glue, to prevent light from penetrating and resulting in light leakage.

The conductors 30 are provided on and protrude from the control chip 20 and are electrically connected to the electrical contacts of the control chip 20. The conductors 30 are encapsulated by the first packaging member 10 and the ends of the conductors 30 facing away from the control chip 20 are flush with the first surface 11. It may be understood that the conductors 30 are also partly provided inside the first packaging member 10, and the ends of the conductors 30 facing away from the control chip 20 are flush with the first surface 11, so that the control chip 20 may be electrically connected to external through the conductors 30.

The wire pattern layer 40 is provided on the first surface 11 and is electrically connected to the plurality of conductors 30 so that the control chip 20 is electrically connected to the wire pattern layer 40 via the conductors 30.

At least one light emitting element 50 is located on the first surface 11 and electrically connected to the wire pattern layer 40, and electrically connected to the control chip 20 through the wire pattern layer 40. That is, the mounting position of the light emitting element 50 on the first surface 11 may be adjusted by setting differently shaped wire pattern layer 40, and the mounting is flexible.

The second packaging member 61 encapsulates the light emitting element 50 and is affixed to the first surface 11 and the wire pattern layer 40, and the light beam emitted by the light emitting element 50 may travel outward through the second packaging member 61. That is to say, the second packaging member 61 may provide sufficient protection for the light emitting element 50 to prevent the light emitting element 50 from being exposed to the air, and also avoid failure resulted from mechanical damage.

It is understood that the second packaging member 61 is made of a light transparent material, for example, a transparent epoxy resin, etc., to ensure the luminous efficiency of the light emitting element 50.

Among them, the control chip 20 may be, for example, a driver chip for driving the light emitting element 50 to light up, or may be a variety of microprocessors; the light emitting element 50 may be one or more of red light emitting diode, blue light emitting diode and green light emitting diode.

The package structure 100 provided in this disclosure includes a first packaging member 10, a control chip 20, a conductor 30, a wire pattern layer 40, a light emitting element 50 and a second packaging member 61, where the control chip 20 is encapsulated by the first packaging member 10 and electrically connected to the wire pattern layer 40 through the conductor 30. Because both the wire pattern layer 40 and the light emitting element 50 are provided on the first packaging member 10 and the second packaging member 61 is used for packaging, the light emitting element 50 and the control chip 20 are vertical stacked, effectively organizing the spatial arrangement. As compared with the existing flat package, the package structure 100 has it size reduced, effectively solving the technical problem that the package product integrating the LED and the control chip 20 has large size.

It is understood that in one embodiment where the light emitting element 50 of the package structure 100 includes a red light emitting diode, a blue light emitting diode and a green light emitting diode, the conductors 30 correspond to the light emitting element 50 through the wire pattern layer 40, and the illumination of the three types of light emitting diodes may be control respectively, that is, the three light emitting diodes are controlled independently of each other.

Please refer again to FIGS. 1 and 2. The electrical contacts of the control chip 20 are facing the first surface 11, and the electrical contacts of the control chip 20 are electrically connected to the conductors 30. In this way, no wire connection is required between the conductors 30 and the control chip 20, which saves planar space improves electrical conduction, and provides reliable connection.

In addition, the electrical contacts of the light emitting element 50 are facing the first surface 11, so that the electrical contacts of the light emitting element 50 may be directly connected to the wire pattern layer 40 without wire bonding, which saves planar space, improves electrical conduction and provides reliable connection.

In this embodiment, the conductors 30 may be prepared on the electrical contacts of the control chip 20 by a bumping process, and the conductors 30 are metal bumps, for example, gold bumps, tin-lead bumps, etc. It is understood that it is also possible to prepare the conductors 30 on the electrical contacts of the control chip 20 by a metal placement process in other embodiments of this disclosure, which is not limited herein.

It is understood that the ends of the conductors 30 facing away from the control chip 20 are flush with the first surface 11, such that the wire pattern layer 40 may be prepared on the flush planar surface, and the ends of the conductors 30 are not covered by the first packaging member 10, thus ensuring direct contact and electrical connection between the ends and the wire pattern layer 40. In addition, as compared with the case where traditional wire bonding is applied, the wire pattern layer 40 has a larger area and engages to the first surface 11, so it may reflect light, and increases the light output from the package structure 100. Besides, the large wire pattern layer 40 engaging to the first surface 11 may also form a metal shield on the first surface 11, effectively improving the electromagnetic compatibility and protecting the control chip 20.

Please refer to FIGS. 1 and 2. In one embodiment of the present disclosure, a plurality of electrical connectors 13 is provided inside the first packaging member 10. The electrical connectors 13 are, for example, conducting channels perpendicular to the first surface 11 and running through the first packaging member 10 and having one end connected to the wire pattern layer 40. In this embodiment, the conducting channel may be composed of a through hole in the first packaging member 10 and the conductive material filled in the through hole. Thus, the control chip 20 encapsulated in the first packaging member 10, the light emitting element 50 encapsulated in the second packaging member 61 and the conducting channels are electrically connected to each other through mold via hole & Re-Distribution layer without wire connection, and the structure is simple.

In addition, in another embodiment of the disclosure, the electrical connectors 13 may also be other structures, for example, the electrical connectors 13 may also be conducting cylinder perpendicular to the first surface 11 and running through the first packaging member 10 and having one end connected to the wire pattern layer 40. In the embodiment, the conducting cylinders may be a metal copper cylinder, which ensures not only stable electrical conductivity of the electrical connectors 13, but also low cost of preparation.

Please refer to FIGS. 1 and 2. In this embodiment, the package structure 100 further includes a plurality of pins 70, which are affixed to the second surface 12 and connected to the electrical connectors 13 at their ends away from the wire pattern layer 40. In this way, the package structure 100 may be electrically connected to an external electronic component through the pins 70, and the control chip 20 may receive electrical signals sent from an external control device through the pins 70 to control the light emission of the light emitting element 50, such as its brightness or color temperature, etc. The electrical connectors 13 and the pins 70 may be positioned at a peripheral side of the first packaging member 10, to facilitate the electrical connection between the pins 70 and an external electronic component. In addition, the wire pattern layer 40, the pins 70, the light emitting element 50 and the control chip 20 are generally vertically stacked, without taking up planar space, improving the utilization of the space of the package structure 100.

It is understood that the wire pattern layer 40 is electrically connected to the control chip 20, the light emitting element 50, and the pins 70, and the pins 70 serve as a medium for the electrical connection between the package structure 100 and the external control device and are used for connecting electrical contacts of the external control device.

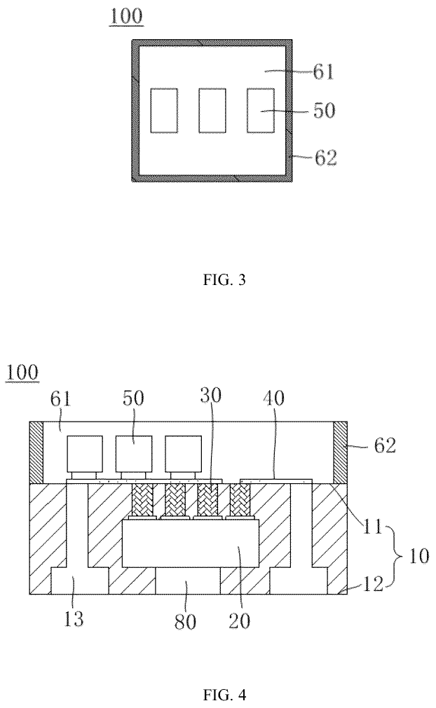

Please refer to FIGS. 2 and 3. In an embodiment of the present disclosure, the package structure 100 further includes a third packaging member 62, which is connected to the first packaging member 10 and around the peripheral side of the second packaging member 61 connecting to the first surface 11. Both the third packaging member 62 and the first packaging member 10 are made of opaque material. In this way, the third packaging member 62 and the first packaging member 10 form a shield for the light emitting element 50, and the light beam emitted by the light emitting element 50 under an instruction of the control chip 20 may only travel outward through an unshielded part of the second packaging member 61, i.e., the top of the package structure 100. Thereby, light leakage may be avoided from other locations, especially from the bottom and the side of the package structure 100, improving the packaging quality. The material of the third packaging member 62 may be the same as the material of the first packaging member 10, and both are opaque epoxy resin such as black glue, to have an improved performance on light leakage elimination.

Please refer to FIGS. 1 and 2. In this embodiment, the side of the third packaging member 62 facing away from the first surface 11 is flush with the side of the second packaging member 61 facing away from the first surface 11, and the outer side of the third packaging member 62 perpendicular to the first surface 11 is flush with the outer side of the first packaging member 10 perpendicular to the first surface 11. In this way, the outer edge of the package structure 100 is flat.

Please refer to FIGS. 1 and 3. In one embodiment of the present disclosure, the package structure 100 includes a plurality of light emitting elements 50, for example, one red light emitting diode, one blue light emitting diode, and one green light emitting diode, and the plurality of light emitting elements 50 are located in the middle of the first surface 11. It may be understood that the mixed light from the package structure 100 will be more uniform in case where the plurality of light emitting elements 50 are located in the middle of the first surface 11.

Since the control chip 20 and the light emitting elements 50 are on different surfaces, the mounting position of the light emitting elements 50 is not affected by the location of the control chip 20, thereby the light emitting members 50 may be placed close to or at the optical center of the overall package structure 100, so as to improve the uniformity of the mixed light and the light emitting efficiency. It may be understood that in other embodiments of the present disclosure, the projection of the plurality of light emitting elements 50 on the first surface 11 overlaps at least partially with the projection of the control chip 20 on the first surface 11.

### Second Embodiment

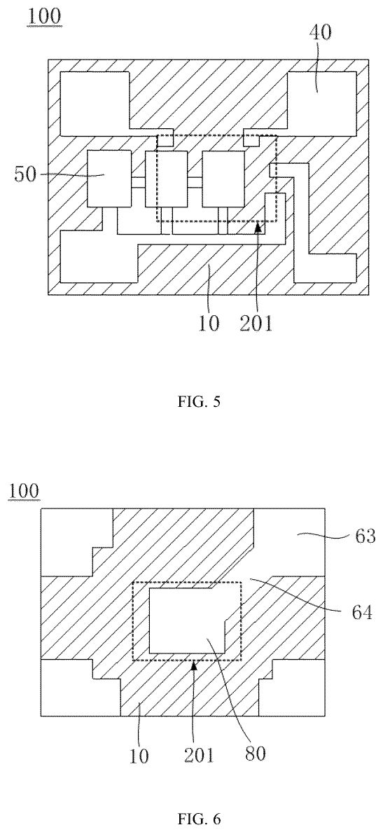

Please refer to FIGS. 4 to 6. The structure of the package structure 100 provided in the second embodiment of this disclosure is substantially the same as that of the package structure 100 in the first embodiment, and both includes a first packaging member 10, a control chip 20, a plurality of conductors 30, a wire pattern layer 40, at least one light emitting element 50, a second packaging member 61 and a third packaging member 62, and the connections between each of the above components are the same as those in the first embodiment. Therefore, the technical solution of the embodiment has all the benefits brought about by the technical solution of the above-mentioned first embodiment, which will not be repeated here again.

The differences between the package structure 100 in this embodiment and the package structure 100 in the first embodiment are that the package structure 100 in this embodiment further includes a metal member 80, which is provided to the control chip 20 at the side away from the conductors 30 and covers at least part of the surface of the control chip 20. The metal member 80 is encapsulated by the first packaging member 10 and may be grounded in later use, to help the control chip 20 to resist electromagnetic wave interference, thereby improving the electromagnetic immunity of the package structure 100.

In the embodiment, the side of the control chip 20 facing away from the conductors 30 may be partially covered by the metal member 80, or the side of the control chip 20 facing away from the conductors 30 may be fully covered by the metal member 80. That is, the metal member 80 may be greater than, equal to, or smaller than the control chip 20.

Please refer to FIGS. 4 to 6. In the embodiment of the present disclosure, the side of the metal member 80 facing away from the control chip 20 is flush with the second surface 12, that is, the end of the metal member 80 facing away from the control chip 20 is not covered by the first packaging member 10 to facilitate heat dissipation of the control chip 20. The package structure 100 further includes a grounded zone 63 provided on the second surface 12, and the grounded zone 63 may be electrically connected to the metal member 80 through an extension electrode sheet 64, and the grounded zone 63 may be electrically connected to the conductors 30 through the electrical connectors 13 and the wire pattern layer 40 in turn.

Specifically, the extension electrode sheet 64 is located on the second surface 12 and has its two ends connected respectively to the end of the metal member 80 and the grounded zone 63. The grounded zone 63 is connected to the electrical connectors 13 to realize electrical connection. Since the electrical connectors 13 is electrically connected to part of the wire pattern in the wire pattern layer, and the part of the wire pattern can be electrically connected to the side of the control chip 20 facing the first surface 11 through the conductors 30, the upper and lower surfaces of the control chip 20 are partially or completely covered with metal, and the metal is connected to the grounded zone 63, which can effectively enhance the electromagnetic interference shielding performance of the control chip 20.

It will be understood that the thickness of the electrical connectors 13 within the first packaging member 10 is greater than the sum of the thicknesses of the control chip 20 and the metal member 80. Where the thickness is the dimension of the electrical connectors 13 along the direction perpendicular to the first surface 11 and the second surface 12, and the same goes to the thicknesses of the control chip 20 and the metal member 80.

Please refer to FIGS. 4 to 6. In this embodiment, the area of the control chip 20 on the first surface 11 or second surface 12 of the first packaging member 10 is defined as a control area 201. Part of the projection of the plurality of light emitting elements 50 on the first surface 11 is outside of the control area 201, while another part of the projection of the plurality of light emitting elements 50 on the first surface 11 is within the control area 201. But this is not a limitation. For example, in a further embodiment, the projection of the plurality of light emitting elements 50 may also be entirely within the control area 201. That is, the projection of the plurality of light emitting elements 50 on the first surface 11 overlaps at least partially with the projection of the control chip 20 on the first surface 11.

The light emitting element 50 and control chip 20 in the package structure 100 of this disclosure are designed to be vertical stacked, which has effectively organized the spatial arrangement, reduced the size of the package structure 100 as compared with the existing flat package, and effectively solved the technical problem that the package product integrating the LED and the control chip 20 has large size. In addition, the additionally arranged metal member 80 may ensure the control chip 20 to have better electromagnetic immunity when in use.

Embodiments of a second aspect of the present disclosure provide a packaging method, which may be used to prepare the package structure in any of the embodiments of the first aspect, please refer to the third and fourth embodiments for details.

### Third Embodiment

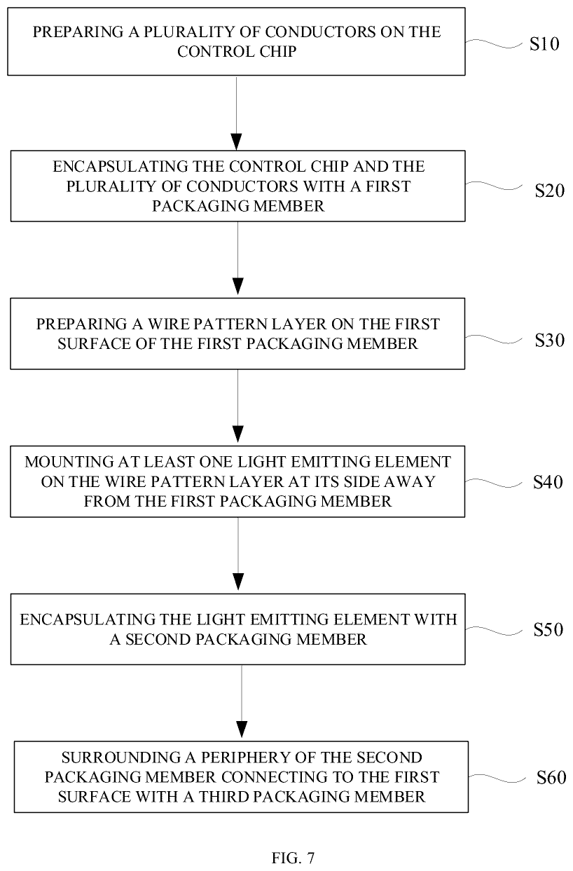

Please refer to FIGS. 7 to 12. The packaging method provided in this embodiment includes:

At S10, a plurality of conductors 30 are prepared on the control chip 20, and the conductors 30 are electrically connected to the electrical contacts of the control chip 20.

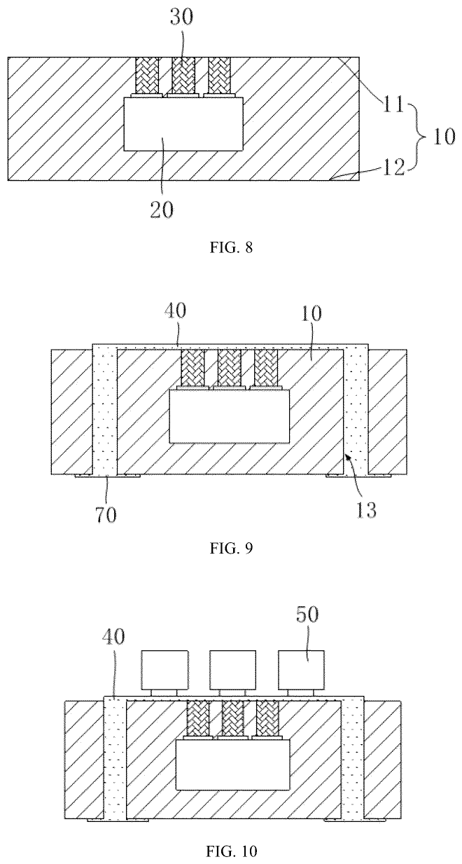

As shown in FIG. 8, conductive members 30 can be prepared on the electrical contacts of the control chip 20 by a wafer bumping process or by a metal placement process to ensure electrical connection therebetween. Without any traditional wire bonded as electrical connectors, the above may reduce space for wire bonding, improve electrical conduction, and have a more robust and reliable connection.

In addition, in this embodiment, prior to S10, a plurality of control chips 20 may be evenly distributed on a same carrier, such that the plurality of control chips 20 may each be provided on the contacts surface (i.e., the surface where the electrical contacts are provided) with corresponding conductors 30 simultaneous during one wafer bumping process or one metal placement process, to improve production efficiency.

At S20, the control chip 20 and the plurality of conductors 30 are encapsulated with a first packaging member 10, and the control chip 20 is not exposed from the first packaging member 10.

As shown in FIG. 8, by making the first packaging member 10 on the control chip 20 and the conductors 30, the control chip 20 and the plurality of conductors 30 may be encapsulated as a whole and without the need for additional substrate, and potential issues such as contamination, mechanical damage resulted from an exposed control chip 20 may be avoided. In addition, the exposed ends of the conductors 30 may ensure later electrical connection.

Specifically, please refer to FIG. 8. The control chip 20 and the conductors 30 are encapsulated with an opaque first packaging member 10, and the ends of the conductors 30 facing away from the control chip 20 are exposed from the first packaging member at a side of the first packaging member 10 which side is defined as the first surface 11, and the other side of the first packaging member 10 is the second surface 12. It may be understood that the electrical contacts of the control chip 20 are facing the first surface 11.

At S30, a wire pattern layer 40 is prepared on the first surface 11 of the first packaging member 10, and the wire pattern layer 40 is electrically connected with the plurality of conductors 30.

Specifically, please refer to FIGS. 8 and 9. The wire pattern layer 40 may be prepared on the first surface 11 of the first packaging member 10 by a process such as Re-distribution Layer. The wire pattern layer 40 is in direct contact with the conductors 30 to ensure electrical connection therebetween.

At S40, at least one light emitting element 50 is mounted on the wire pattern layer 40 at its side away from the first packaging member 10.

In this way, the light emitting element 50 may be electrically connected to the control chip 20 through the wire pattern layer 40 and the conductors 30 without wire bonding. In addition, the light emitting element 50, the wire pattern layer 40, the conductors 30 and the control chip 20 are vertically stacked, which may reduce the required planar space, and effectively reduce the size of and the space occupied by the package structure 100.

Please refer to FIG. 10. In the above step, a plurality of light emitting elements 50, including a red light emitting diode, a blue light emitting diode and a green light emitting diode, are mounted in the middle of the first surface 11. In addition, the electrical contacts of the light emitting elements 50 are in direct contact with the wire pattern layer 40 to ensure electrical connection therebetween and are electrically connected to the control chip 20 through the conductors 30.

Please refer to FIG. 2 and FIG. 9 again. The embodiments of the present disclosure also prepares a plurality of electrical connectors 13 such as conducting channels perpendicular to the first surface 11 through mold via hole process, and prepares pins 70 that are affixed to the second surface 12 and connected to the conducting channels at their ends away from the wire pattern layer 40, so that the control chip 20 embedded in the first packaging member 10 is electrically connected to an external controller through the conductors 30, the wire pattern layer 40, the conducting channels, and the pin 70 without wire bonding connection, and the structure is simple.

At S50, the light emitting element 50 is encapsulated with a second packaging member 61, and the second packaging member 61 is affixed to the first surface 11 and the wire pattern layer 40.

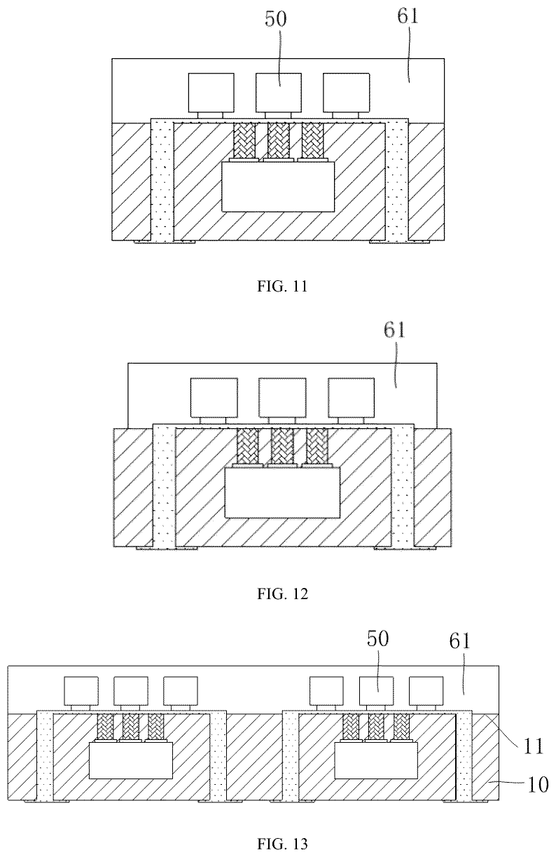

Since the second packaging member 61 is made of a light transparent material, it may protect the light emitting element 50 and may also ensure the light output efficiency of the package structure 100. Specifically, please refer to FIG. 11. The first surface 11 of the first packaging member 10, the wire pattern layer 40, and the light emitting element 50 are encapsulated with the light transparent second packaging member 61 and cured.

The above packaging method may allow the light emitting element 50, the wire pattern layer 40, the conductors 30 and the control chip 20 to be vertically stacked, which may reduce the required planar space and reduce the size of the package structure 100. The light emitting element 50 may be electrically connected to the control chip 20 through the wire pattern layer 40 and the conductors 30, which reduces wire patterning.

Please refer to FIGS. 1, 2 and 7. In an embodiment of the present disclosure, after step S50, the packaging method further includes:

At S60, a peripheral side of the second packaging member 61 connecting to the first surface 11 is surrounded with a third packaging member 62.

Since both the third packaging member 62 and the first packaging member 10 are made of opaque material, further encapsulating the peripheral side of the second packaging member 61 connecting to the first surface 11 with the third packaging member 62 after the light emitting element 50 has been encapsulated with the light transparent second packaging member 61 may prevent light leak of the light emitting element 50 from the bottom and the side of the package structure 100.

Specifically, please refer to FIG. 2, FIG. 11 and FIG. 12. The second packaging member 61 is diced at the peripheral side, and the peripheral side of the second packaging member 61 connecting to the first surface 11 is encapsulated by encapsulating with and curing of the opaque third packaging member 62.

It may be understood that in other embodiments of the present disclosure, the step of dicing at the peripheral side of the second packaging member 61 may also be omitted, that is, the third packaging member 62 may encapsulate the peripheral side of the resulted structure directly after encapsulating the first surface 11 of the first packaging member 10 and the light emitting element 50 with the second packaging member 61, i.e. the structure shown in FIG. 11, which may also have the same effect that no light leak come from the bottom and the side of the package structure 100.

The packaging method provided in this disclosure may allow the light emitting element 50, the wire pattern layer 40, the conductors 30 and the control chip 20 to be vertically stacked, which may reduce the required planar space and thus reduce the size of the package structure 100.

### Fourth Embodiment

In this embodiment, the packaging method includes steps S10 to S60, which are substantially the same as in the third embodiment, and has same technical effect. The details will not be repeated. The difference is that in this embodiment, the control chip 20 is additionally provided with a metal member 80 and an electrical connector 13, where the electrical connector 13 is a conducting cylinder.

Accordingly, in this embodiment, prior to step S20, i.e., prior to encapsulating the control chip 20 and the plurality of conductors 30 with the first packaging member 10, the packaging method further includes, preparing the metal member 80 and arranging the metal member 80 on the control chip 20 at its side away from the conductors 30 and making the metal member 80 to be affixed to the control chip 20.

Specifically, the metal member 80 with a designed shape, and electrical connectors 13 are affixed together to a carrier, such as glass, where the metal member 80 is a partially etched copper sheet and the electrical connectors 13 are conducting cylinders. Then, the control chip 20 with the plurality of conductors 30 is bonded to the metal member 80 with a die bond and cured. In this way, the electromagnetic immunity of the control chip 20 may be improved, and the electrical connection of the conducting cylinder is more stable than the conductive channel.

The packaging method provided in this disclosure may prepare multiple structurally identical package structures 100 in one same batch. For example, in a fifth embodiment of this disclosure, the packaging method includes steps S10 to S40, which are substantially the same as in the third embodiment, and have same technical effect. The details will not be repeated.

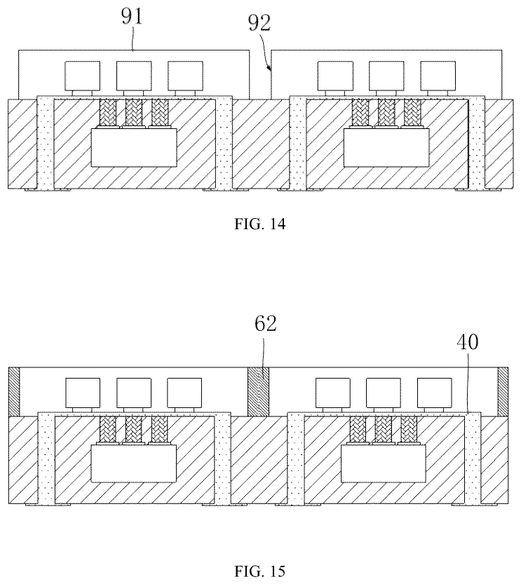

Further, please refer to FIGS. 13 and 14. In this embodiment, at step S50, the light emitting element 50 is encapsulated with a second packaging member 61 and the second packaging member 61 is affixed to the first surface 11 and the wire pattern layer 40, which includes:

At S51, the light emitting element 50 is encapsulated with the second packaging member 61, which is affixed to the first surface 11 and the wire pattern layer 40.

At S52, the second packaging member 61 is diced to obtain a plurality of dice 91, and a gap 92 exists between adjacent dice 91.

In this embodiment, a plurality of light emitting elements 50 are mounted on the wire pattern layer 40 at its side away from the first packaging member 10. After dicing, each cut unit 91 includes one light emitting unit, and each light emitting unit includes three light emitting elements 50 which are a red light emitting diode, a blue light emitting diode and a green light emitting diode, respectively. in this way, the light transparent second packaging member 61 may protect the light emitting elements 50 and the wire pattern layer 40 and also ensure the illumination of the light emitting elements 50. Besides, encapsulating a plurality of light emitting units simultaneously may improve operational efficiency.

Further, please refer to FIG. 15. In this embodiment, at step S60, the peripheral side of the second packaging member 61 connecting to the first surface 11 is surrounded with the third packaging member 62, which includes:

At S61, the gap 92 is filled with the third packaging member 62 so that the third packaging member 62 surrounds the peripheral side of the second packaging member 61 connecting to the first surface 11 to form a plurality of connected package structures 100.

At S62, the plurality of connected package structures 100 are subjected to a singulation process. In this way, the package structures 100 may be prepared in bulk, improving production efficiency.

The above packaging method may allow the light emitting element 50, the wire pattern layer 40, the conductors 30 and the control chip 20 to be vertically stacked, which may reduce the required planar space, and thus reduce the size of the package structure 100. As the opaque first packaging member 10 encapsulates the control chip 20 entirely, no additional substrate is needed, and potential issues such as contamination, mechanical damage resulted from an exposed control chip 20 may be avoided. In addition, multiple structurally identical package structures 100 may be prepared simultaneously, improving production efficiency and reducing production costs.

The above-mentioned embodiments are merely intended for describing but not for limiting the technical solutions of the present disclosure. Although the present disclosure is described in detail with reference to the above-mentioned embodiments, it should be understood by those skilled in the art that, the technical solutions recited in each of the above-mentioned embodiments may still be modified, or some of the technical features may be equivalently replaced, while these modifications or replacements do not make the essence of the corresponding technical solutions depart from the spirit and scope of the technical solutions of each of the embodiments of the present disclosure, and should be included within the scope of the present disclosure.

1. A package structure, comprising:
a first packaging member having a first surface and a second surface oppositely arranged;
a control chip covered by the first packaging member;
a plurality of conductors provided on and protruding from the control chip and electrically connected to electrical contacts of the control chip, the conductors being covered by the first packaging member, and ends of the conductors facing away from the control chip being flush with the first surface;
a wire pattern layer disposed on the first surface and electrically connected to the conductors;
at least one light emitting element located on the first surface and electrically connected to the control chip via the wire pattern layer; and
a second packaging member covering the light emitting element and affixed to the first surface and the wire pattern layer, a light beam emitted by the light emitting element being able to travel outward through the second packaging member.

2. The package structure according to claim 1, wherein the second packaging member is made of a light transparent material and the electrical contacts of the control chip are facing the first surface.

3. The package structure according to claim 1, wherein a plurality of electrical connectors are provided inside the first packaging member, the electrical connector is a conducting channel or a conducting cylinder, the electrical connector is perpendicular to the first surface and penetrates the first packaging member, and one end of the electrical connector is connected to the wire pattern layer.

4. The package structure according to claim 3, wherein the control chip is not exposed from the first packaging member, the package structure further comprises a plurality of pins, the pin is affixed to the second surface and connected to one end of the electrical connector away from the wire pattern layer, and electrical contacts of the light emitting element are facing the first surface.

5. The package structure according to claim 3, wherein the package structure further comprises a metal member, the metal member is provided on one side of the control chip away from the conductors and covers at least part of a surface of the control chip, and the metal member is covered by the first packaging member.

6. The package structure according to claim 5, wherein a side of the metal member facing away from the control chip is flush with the second surface, and the package structure further comprises a grounded zone provided on the second surface; and
The grounded zone is electrically connected to the metal member, and the grounded zone is electrically connected to one of the conductors through one of the electrical connectors and the wire pattern layer.

7. The package structure according to claim 1, wherein the package structure further comprises a third packaging member, and the third packaging member is connected to the first packaging member and surrounds a peripheral side of the second packaging member connecting to the first surface; both the third packaging member and the first packaging member are made of opaque material; a side of the third packaging member facing away from the first surface is flush with a side of the second packaging member facing away from the first surface, and an outer side of the third packaging member perpendicular to the first surface is flush with an outer side of the first packaging member perpendicular to the first surface.

8. The package structure according to claim 7, wherein the package structure comprises a plurality of the light emitting elements and the light emitting elements are located in the middle of the first surface.

9. A packaging method for preparing a package structure, comprising:
preparing a plurality of conductors on a control chip, the conductors being electrically connected to electrical contacts of the control chip;
covering the control chip and the conductors with a first packaging member, the control chip not being exposed from the first packaging member;
preparing a wire pattern layer on a first surface of the first packaging member, the wire pattern layer being electrically connected to the conductors;
mounting at least one light emitting element on one side of the wire pattern layer away from the first packaging member; and
covering the light emitting element with a second packaging member, the second packaging member being affixed to the first surface and the wire pattern layer.

10. The packaging method according to claim 9, wherein the packaging method further comprises:
surrounding a peripheral side of the second packaging member connecting to the first surface with a third packaging member;
wherein said preparing the conductors on the control chip comprises preparing the conductors by a wafer bumping process or a metal placement process; and
prior to said covering the control chip and the conductors with the first packaging member, the method further comprises preparing a metal member, the metal member being provided on one side of the control chip away from the conductors.

11. The package structure according to claim 2, wherein the package structure further comprises a third packaging member, and the third packaging member is connected to the first packaging member and surrounds a peripheral side of the second packaging member connecting to the first surface; both the third packaging member and the first packaging member are made of opaque material; a side of the third packaging member facing away from the first surface is flush with a side of the second packaging member facing away from the first surface, and an outer side of the third packaging member perpendicular to the first surface is flush with an outer side of the first packaging member perpendicular to the first surface.

12. The package structure according to claim 6, wherein the package structure further comprises a third packaging member, and the third packaging member is connected to the first packaging member and surrounds a peripheral side of the second packaging member connecting to the first surface; both the third packaging member and the first packaging member are made of opaque material; a side of the third packaging member facing away from the first surface is flush with a side of the second packaging member facing away from the first surface, and an outer side of the third packaging member perpendicular to the first surface is flush with an outer side of the first packaging member perpendicular to the first surface.

13. The package structure according to claim 8, wherein a projection of the light emitting elements on the first surface overlaps at least partially with a projection of the control chip on the first surface.
